(19) United States
(12) Patent Application Publication
(10) Pub. No.: US 2025/0183176 A1
(43) Pub. Date: Jun. 5, 2025

(54) MICROELECTRONIC DEVICES COMPRISING SILICON CARBON MATERIALS AND RELATED METHODS

(71) Applicant: Micron Technology, Inc., Boise, ID (US)

(72) Inventors: Vivek Y. Yadav, Boise, ID (US); Li Wei Fang, Taichung (TW); Albert P. Chan, Boise, ID (US); Sanjeev Sapra, Boise, ID (US); Shing-Chiang Huang, Boise, CA (US)

(21) Appl. No.: 18/941,600

(22) Filed: Nov. 8, 2024

Related U.S. Application Data
(60) Provisional application No. 63/606,557, filed on Dec. 5, 2023.

(51) Int. Cl. H01L 23/532; H01L 21/3213; H01L 21/768; H01L 23/528; H10B 12/00

(52) U.S. Cl. CPC H01L 23/53271; H01L 21/32134; H01L 21/76862; H01L 23/5283; H01L 23/5329; H10B 12/488

(57) ABSTRACT

A microelectronic device comprises active areas, shallow trench isolation structures, word lines, word line insulative structures, and a dielectric stack over the active areas on a base material. A first conductive material is vertically adjacent to an active area of the active areas and is between laterally adjacent word line insulative structures in a first horizontal direction. A second conductive material is vertically adjacent to the first conductive material, is between the laterally adjacent word line insulative structures, and between laterally adjacent portions of the dielectric stack in the first horizontal direction. The silicon carbon material is on sidewalls of the dielectric stack. A digit line is vertically adjacent to the second conductive material and to the dielectric stack, and is between laterally adjacent digit line openings in a second horizontal direction substantially orthogonal to the first horizontal direction. Additional microelectronic devices and related methods are also disclosed.

### CROSS-REFERENCE TO RELATED APPLICATION

This application claims the benefit under 35 U.S.C. § 119 (e) of U.S. Provisional Patent Application Ser. No. 63/606,557, filed Dec. 5, 2023, the disclosure of which is hereby incorporated herein in its entirety by this reference.

### TECHNICAL FIELD

Embodiments disclosed herein relate to apparatus (e.g., microelectronic devices) and methods of forming microelectronic devices. More particularly, embodiments of the disclosure relate to methods of using a silicon carbon material to form smaller openings, and to related microelectronic devices containing the silicon carbon material.

### BACKGROUND

Electronic device designers desire to increase the level of integration or density of features within an electronic device by reducing the dimensions of individual features and by reducing the separation distance between neighboring features. In addition, electronic device designers often desire to design architectures that are not only compact, but offer performance advantages, as well as simplified designs. A relatively common electronic device is a memory device. A memory device may include a memory array having a number of memory cells arranged in a grid pattern. One type of memory cell is a dynamic random access memory (DRAM) device, which is a volatile memory device that may lose a stored state over time unless the DRAM device is periodically refreshed by an external power supply. In the simplest design configuration, a DRAM cell includes one access device (e.g., a transistor) and one storage device (e.g., a capacitor). Modern applications for memory devices may utilize vast numbers of DRAM unit cells, arranged in an array of rows and columns. The DRAM cells are electrically accessible through digit lines and word lines arranged along the rows and columns of the array.

Dry etch processes are used in many memory device fabrication processes due to directionality of the plasma that is achieved during the dry etch process. The plasma directionality of the dry etch process enables materials to be etched to exhibit vertical sidewalls. The dry etch processes are used, for example, in processes where small features are desired. Openings are formed by photolithography processes in a material to a desired critical dimension (CD) and a liner is conformally formed on sidewalls of the material defining the openings. Portions of the liner within the openings are removed by the dry etch processes, while remaining portions of the liner narrow (e.g., reduce, shrink) the size of the openings, enabling the small features to be formed in the reduced-sized openings. Materials of the features are subsequently formed in the openings and the resulting features are smaller in size than the CD of the openings. As sizes of the features of memory devices continue to decrease, the ability to form the openings at the desired CD and remove the desired portions of the liner becomes harder. The dry etch processes used to remove portions of the materials cause surface damage to underlying materials or produce undesirable profiles in the underlying materials. Surface damage to the underlying materials may result in reduced electrical performance. The liner may also exhibit shoulders, which cause shorting between adjacent features.

### BRIEF DESCRIPTION OF THE DRAWINGS

FIG. 1A is a simplified, partial top-down view of a microelectronic device structure in accordance with embodiments of the disclosure;

FIGS. 1B through 1G are simplified partial cross-sectional views showing a method of forming the microelectronic device structure of FIG. 1A;

FIG. 2A is a simplified, partial top-down view of a microelectronic device structure in accordance with embodiments of the disclosure;

FIGS. 2B through 2D are simplified partial cross-sectional views showing a method of forming the microelectronic device structure of FIG. 2A;

FIG. 3 is a simplified block diagram of a microelectronic device (e.g., a DRAM device, a memory device) including a microelectronic device structure in accordance with embodiments of the disclosure; and

FIG. 4 is a simplified block diagram of a system implemented in accordance with some embodiments of the disclosure.

### DETAILED DESCRIPTION

An apparatus (e.g., a microelectronic device structure, a microelectronic device, a semiconductor device, a memory device) that includes a liner adjacent to (e.g., over) one or more materials is disclosed. The liner may include a doped silicon-containing material that also contains carbon atoms (e.g., a carbon doped silicon material, a silicon carbon material). The liner may be conformally formed in an opening. After formation, portions of the liner may be exposed to a plasma treatment act, which may change a chemical composition of the exposed portions of the liner. After conducting the plasma treatment act on the silicon carbon material as initially formed, the exposed portions and unexposed portions of the liner may exhibit different chemical compositions, enabling the exposed portions of the liner to be selectively removed. After the plasma treatment, the exposed portions of the liner may be selectively removed (e.g., selectively etched) from the openings by a wet etch act, while the unexposed portions of the liner remain in the openings, reducing the width of the openings. A conductive material subsequently formed in the openings may form a digit line contact having a smaller width than the width of the openings.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an electronic device or a complete process flow for manufacturing the electronic device and the structures described below do not form a complete electronic device. Only those process acts and structures necessary to understand the embodiments described herein are described in detail below. Additional acts to form a complete electronic device may be performed by conventional techniques.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an” and “the” are intended to include the plural forms as well, unless the context clearly indicates otherwise.

As used herein, “and/or” includes any and all combinations of one or more of the associated listed items.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “opening” means and includes a volume extending through at least one structure or at least one material, leaving a void (e.g., gap) in that at least one structure or at least one material, or a volume extending between structures or materials, leaving a gap between the structures or materials. Unless otherwise described, an “opening” is not necessarily empty of material. That is, an “opening” is not necessarily void space. An “opening” formed in or between structures or materials may comprise structure(s) or material(s) other than that in or between which the hole or slot is formed. And, structure(s) or material(s) “exposed” within an “opening” is (are) not necessarily in contact with an atmosphere or nonsolid environment. Structure(s) or material(s) “exposed” within an “opening” may be adjacent or in contact with other structure(s) or material(s) that is (are) disposed within the “opening.”

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one of the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “conductive material” means and includes an electrically conductive material. The conductive material may include, but is not limited to, one or more of a doped polysilicon, undoped polysilicon, a metal, an alloy, a conductive metal oxide, a conductive metal nitride, a conductive metal silicide, and a conductively doped semiconductor material. By way of example only, the conductive material may be one or more of tungsten (W), tungsten nitride (WN_{y}), nickel (Ni), tantalum (Ta), tantalum nitride (TaN_{y}), tantalum silicide (TaSiₓ), platinum (Pt), copper (Cu), silver (Ag), gold (Au), aluminum (Al), molybdenum (Mo), titanium (Ti), titanium nitride (TiN_{y}), titanium silicide (TiSiₓ), titanium silicon nitride (TiSiₓN_{y}), titanium aluminum nitride (TiAlₓN_{y}), molybdenum nitride (MoNₓ), iridium (Ir), iridium oxide (IrO_{z}), ruthenium (Ru), ruthenium oxide (RuO_{z}), n-doped polysilicon, p-doped polysilicon, undoped polysilicon, and conductively doped silicon.

As used herein, the term “configured” refers to a size, shape, material composition, and arrangement of one or more of at least one structure and at least one apparatus facilitating operation of one or more of the structures and the apparatus in a pre-determined way.

As used herein, the term “dielectric material” means and includes an electrically insulative material. The dielectric material may include, but is not limited to, one or more of an insulative oxide material or an insulative nitride material. A dielectric oxide may be an oxide material, a metal oxide material, or a combination thereof. The dielectric oxide may include, but is not limited to, a silicon oxide (SiOₓ, silicon dioxide (SiO₂)), doped SiOₓ, phosphosilicate glass, borosilicate glass, borophosphosilicate glass, fluorosilicate glass, tetraethylorthosilicate (TEOS), aluminum oxide (AlOₓ), gadolinium oxide (GdOₓ), hafnium oxide (HfOₓ), magnesium oxide (MgOₓ), niobium oxide (NbOₓ), tantalum oxide (TaOₓ), titanium oxide (TiOₓ), zirconium oxide (ZrOₓ), hafnium silicate, a dielectric oxynitride material (e.g., SiOₓN_{y}), a dielectric carboxynitride material (e.g., SiOₓC_{z}N_{y}), a combination thereof, or a combination of one or more of the listed materials with silicon oxide. A dielectric nitride material may include, but is not limited to, silicon nitride.

As used herein, the terms “different chemical composition” or “different material composition” mean and include a chemical composition of a portion of a liner material differing in the relative ratio of one or more chemical elements from a chemical composition of another portion of the liner material. For example, if the liner material is a doped silicon-containing material, the chemical composition of one portion of the liner material may include a higher carbon content than of another portion of the liner material.

As used herein, the term “digit line” may be otherwise known and referred to in the art as a “bit line” or as a “sense line.”

As used herein, the term “electronic device” includes, without limitation, a memory device, as well as semiconductor devices which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may be a 3D electronic device, such as a 3D DRAM device.

As used herein, the term “liner material” or “liner” means and includes a silicon carbon material or a doped silicon-containing material, such as a doped silicon carbon material, formulated to exhibit etch selectivity relative to other exposed materials when subjected to the same etch conditions. The liner may include one or more materials, such as a silicon carbon material, a silicon carbon oxide material, a silicon carbon nitride material, a silicon carbon boride material and one or more other materials, positioned adjacent to one another and that are formulated to exhibit the desired etch selectivity properties.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

As used herein, the term “silicon carbon material” means and includes a material including silicon atoms and carbon atoms, and, optionally one or more of oxygen atoms, nitrogen atoms, or boron atoms. The silicon carbon material may be a stoichiometric compound or a non-stoichiometric compound. Therefore, the term includes silicon carbide, silicon carbon oxide, silicon carbon nitride, silicon carbon oxynitride, or silicon carbon boride. The term “silicon carbon material” may also be used to collectively refer to silicon carbide (SiC) or the doped silicon carbon material.

As used herein, the term “doped silicon carbon material” means and includes a material including silicon atoms, carbon atoms, and one or more of oxygen atoms, nitrogen atoms, or boron atoms. The doped silicon carbon material may include, but is not limited to, a silicon carbon oxide material, a silicon carbon nitride material, or a silicon carbon oxynitride material. The doped silicon carbon material may also include a silicon carbon boride material or a silicon carbon oxyboride carbide material. The term “silicon carbon oxide” is used to refer to the doped silicon carbon material having a general chemical formula of SiC_{y}Oₓ, wherein one or more of the carbon atoms are bonded to the silicon atoms. The term “silicon carbon nitride” is used to refer to the doped silicon carbon material having a general chemical formula of SiCN_{y}, and the term “silicon carbon oxynitride” is used to refer to the doped silicon carbon material having a general chemical formula of SiCOₓN_{y}. The doped silicon carbon materials listed above may be a stoichiometric compound or a non-stoichiometric compound, and values of “x” and “y” may be integers or may be non-integers. The term “doped silicon carbon material” is used to collectively refer to the silicon carbon oxide material, the silicon carbon nitride material, and/or the silicon carbon oxynitride material. Silicon oxide (SiOₓ) including only silicon atoms and oxygen atoms is excluded from the definition of a doped silicon carbon material.

As used herein, the terms “selectively removable” or “selectively etchable” mean and include a material that exhibits a greater removal (e.g., etch) rate responsive to exposure to a given etch chemistry and/or process conditions relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “substrate” means and includes a material (e.g., a base material) or construction upon which additional materials are formed. The substrate may be an electronic substrate, a semiconductor substrate, a base semiconductor layer on a supporting structure, an electrode, an electronic substrate having one or more materials, layers, structures, or regions formed thereon, or a semiconductor substrate having one or more materials, layers, structures, or regions formed thereon. The materials on the electronic substrate or semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma-enhanced CVD), or epitaxial growth. Alternatively, the materials may be grown in situ. Depending on the specific material to be formed, the technique for depositing or growing the material may be selected by a person of ordinary skill in the art.

Unless the context indicates otherwise, the removal of materials described herein may be accomplished by any suitable technique including, but not limited to, etching (e.g., dry etching, wet etching, vapor etching), ion milling, abrasive planarization, or other known methods.

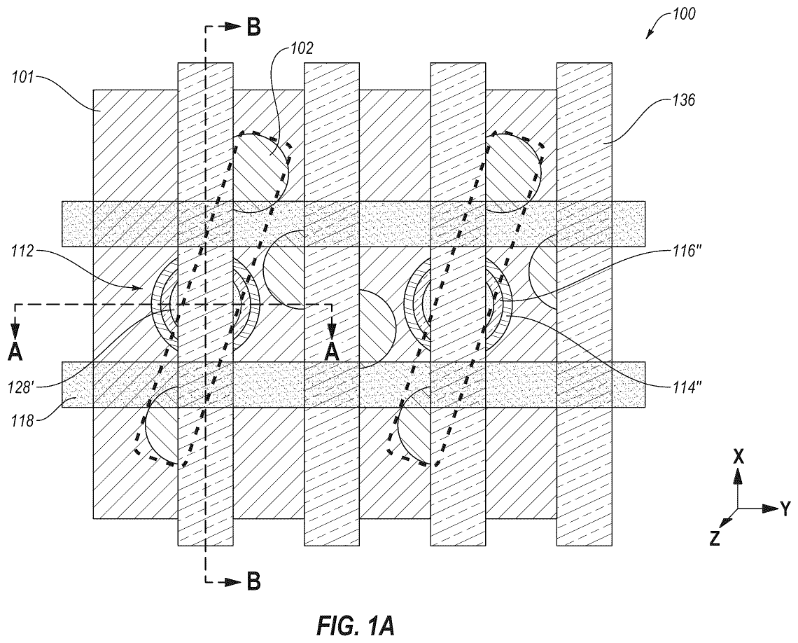

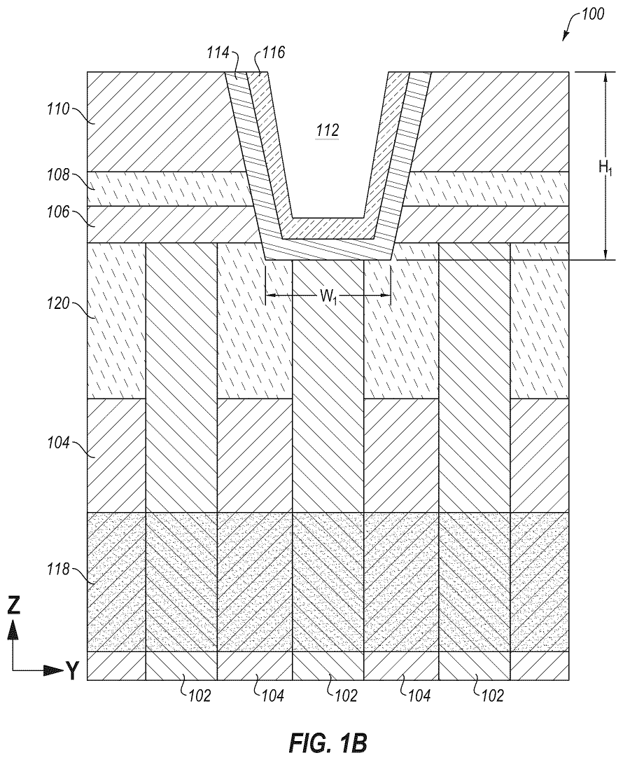

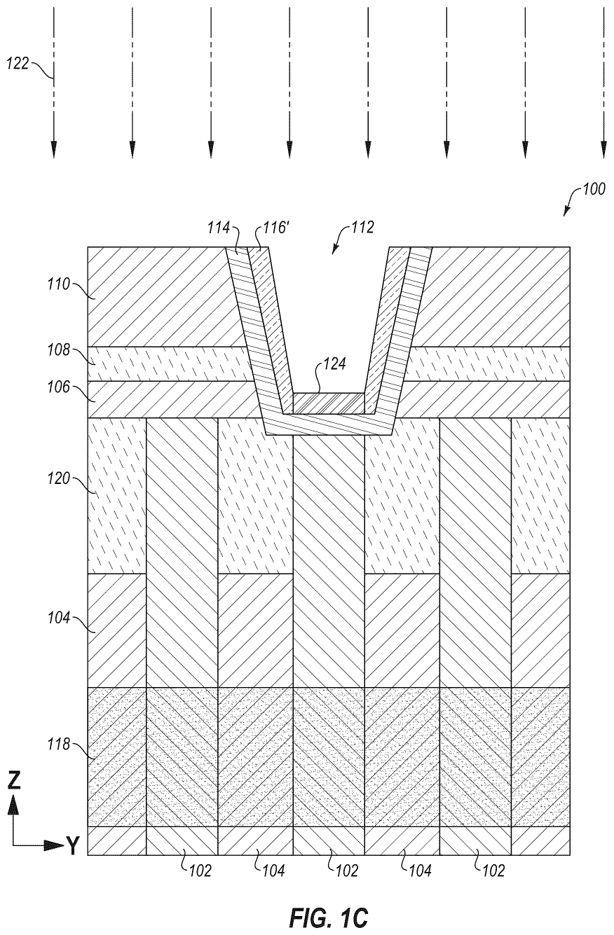

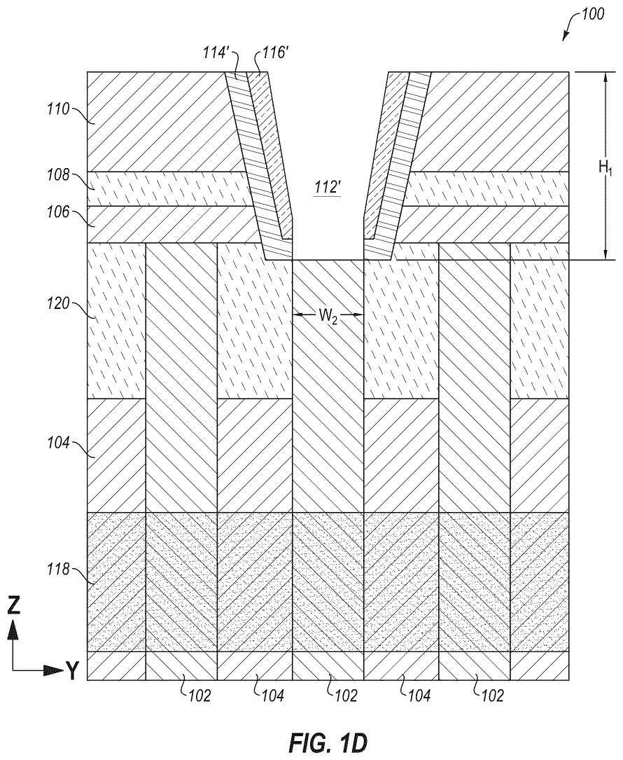

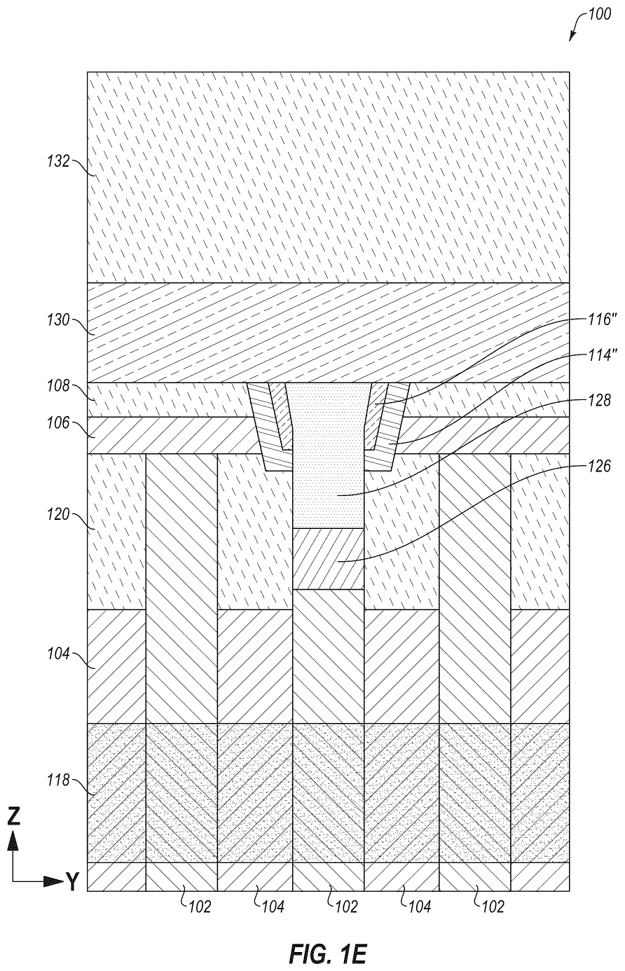

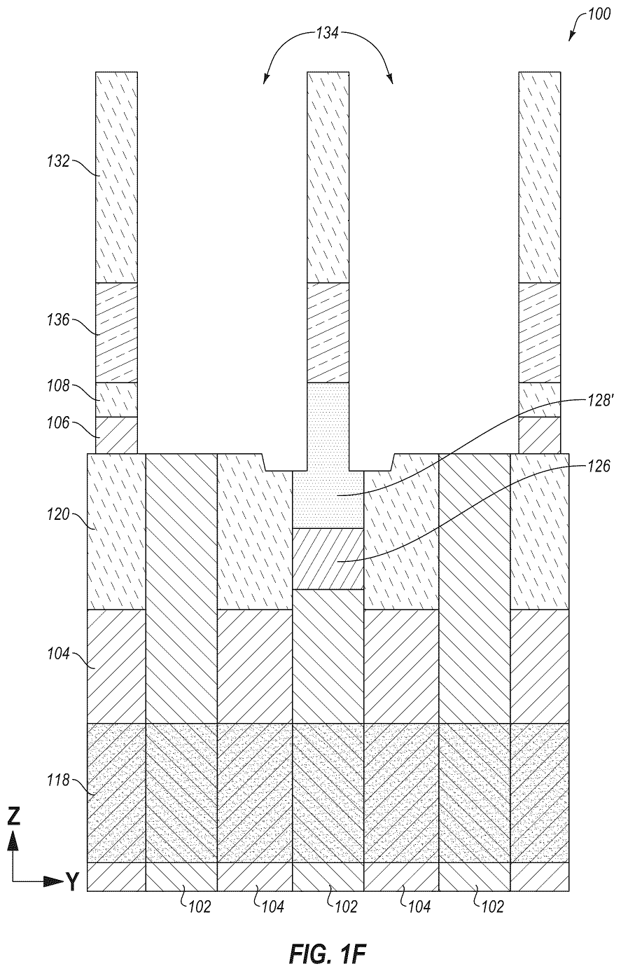

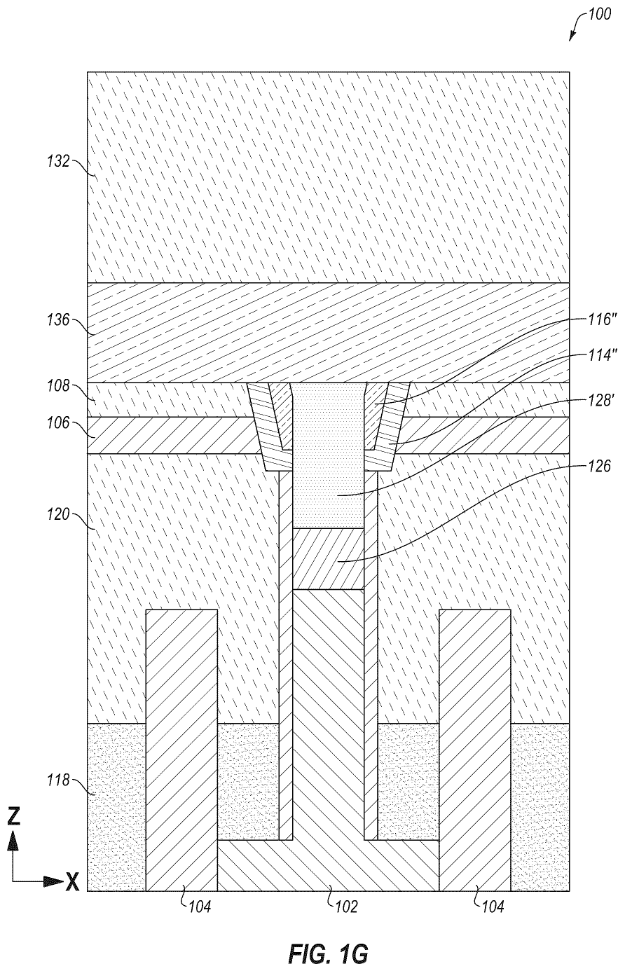

FIG. 1A illustrates a microelectronic device structure 100 (e.g., a microelectronic device; a semiconductor device; a memory device, such as a DRAM device). The microelectronic device structure 100 may include active areas 102, openings 112, liner nitride 114″, liner 116″, word lines 118 (e.g., access line structures, access lines), contact structures 128′ (e.g., digit line contacts), and digit line structures 136 (e.g., digit lines, bit lines). The microelectronic device structure 100 shown in FIG. 1A has been subjected to previous fabrication acts to form these components of a microelectronic device structure 100 on a base material 101, as will be described in further detail with reference to FIGS. 1B through 1G. As shown in FIG. 1A, the microelectronic device structure 100 comprises multiple active areas 102, horizontally offset (e.g., in the X- and Y-directions) from the openings 112. Individual active areas 102 are horizontally offset in the Y-direction from adjacent digit line structures 136, which extend substantially parallel to one another in the X-direction. The openings 112 may comprise filled openings. At the processing stage shown in FIG. 1A, an individual contact structure 128′ is concentrically positioned within a corresponding liner 116″, the individual liner 116″ is concentrically positioned within a corresponding liner nitride 114″, and the individual liner nitride 114″ is concentrically positioned within the horizontal area of a corresponding opening 112. The openings 112 are horizontally interposed (e.g., in the X-direction) between adjacent word lines 118, which extend substantially parallel to one another in the Y-direction. The word lines 118 are horizontally adjacent (e.g., in the X-direction) to the active areas 102 and extend perpendicular to the digit line structures 136.

FIGS. 1B through 1G are simplified partial cross-sectional views showing embodiments of a method of forming the microelectronic device structure 100 of FIG. 1A, where dashed line A-A corresponds to the longitudinal cross section of the microelectronic device structure 100 depicted in FIGS. 1B through 1F and dashed line B-B corresponds to the longitudinal cross section of the microelectronic device structure 100 depicted in FIG. 1G. For clarity in understanding the drawings and related description, some features (e.g., structures, materials, regions) of the microelectronic device structure 100 at the processing stages depicted in FIGS. 1B through 1G and described below with respect to FIGS. 1B through 1G may not be depicted in FIG. 1A, and vice versa. For example, to better illustrate the active areas 102, the openings 112, the liner nitride 114, the liner 116, the word lines 118, and the digit line structures 136 in FIG. 1A, all or portions of the STI structures 104, a first dielectric material 106, a second dielectric material 108, a third dielectric material 110, a word line insulative structure 120, and digit line caps 132 depicted in at least one of FIGS. 1B through 1G are omitted from (i.e., are not depicted in) FIG. 1A. However, it will be understood that any feature depicted in at least one of FIGS. 1A through 1G may be included in the microelectronic device structure 100 of FIG. 1A and/or at least one of the processing stages of FIGS. 1B through 1G.

At the processing stage depicted in FIG. 1B, the microelectronic device structure 100 may further include shallow trench isolation (STI) structures 104, the first dielectric material 106, the second dielectric material 108, the third dielectric material 110, and the word line insulative structures 120 (e.g., word line cap). The active areas 102, STI structures 104, and word line 118 may be formed by conventional techniques. The word lines 118 may be horizontally adjacent (e.g., in the X-direction) to the active areas 102 and horizontally adjacent (e.g., in the X- and Y-directions) to the STI structures 104. The word line insulative structures 120 may be formed to be vertically positioned (e.g., in the Z-direction) above the word lines 118. In addition, the microelectronic device structure 100 may include the first dielectric material 106 vertically overlying (e.g., on, directly on, directly contacting) the active areas 102 and the word line insulative structures 120, the second dielectric material 108 vertically overlying the first dielectric material 106, and the third dielectric material 110 vertically overlying the second dielectric material 108.

The microelectronic device structure 100 at the process stage shown in FIG. 1B may be formed by conventional techniques. The active areas 102 may be formed of silicon, such as a monocrystalline silicon, a doped monocrystalline silicon, or a polysilicon and may be isolated from one another by the STI structures 104, which may be formed of a nitride material (e.g., a silicon nitride (SiN), an oxynitride). By way of example only, the active areas 102 may be formed of silicon and the STI structures 104 may be formed of silicon nitride. The first dielectric material 106 and the third dielectric material 110 may each be formed of the same oxide material, or may be formed of different oxide materials. As a non-limiting example, the first dielectric material 106 and the third dielectric material 110 may include, but are not limited to, a silicon oxide material. The second dielectric material 108 may be formed of a material that is selectively etchable relative to one or more other dielectric materials (e.g., the first dielectric material 106, the third dielectric material 110) used during the fabrication process. The second dielectric material 108 may include, but is not limited to, a silicon nitride material, a silicon oxynitride material, a silicon carbon nitride material, or a silicon carboxynitride material. The second dielectric material 108 may, for example, be a silicon nitride material. The first dielectric material 106, the second dielectric material 108, and the third dielectric material 110 may jointly form a dielectric stack. Alternatively, the dielectric stack may comprise fewer or more materials than the first dielectric material 106, the second dielectric material 108, and the third dielectric material 110.

The microelectronic device structure 100 may include an opening 112 extending downward (e.g., in the Z-direction) into the first dielectric material 106, the second dielectric material 108, the third dielectric material 110, at least one of the active areas 102, and the word line insulative structures 120. The opening 112 may be formed by removing portions of material from the third dielectric material 110 to at least one of the active areas 102 and the word line insulative structure 120. The opening 112 may be formed by conventional techniques. Dimensions of the opening 112 include a CD (e.g., width W₁ in the Y-direction) and a trench depth (e.g., height H₁ in the Z-direction).

The width W₁ of the opening 112 may be defined at the lower boundary (e.g., in the Z-direction) of the opening 112. The opening 112 may have horizontal boundaries at least partially defined by opposing side surfaces (e.g., opposing sidewalls) of the first dielectric material 106, the second dielectric material 108, the third dielectric material 110, and the word line insulative structures 120. The sidewalls of the first dielectric material 106, the second dielectric material 108, the third dielectric material 110, and the word line insulative structures 120 defining the opening 112 may be vertical, substantially vertical, or sloped. Upper surfaces of an active area 102 exposed through (e.g., directly underlying) the opening 112 may be vertically (e.g., in the Z-direction) recessed relative to other active areas 102. Upper surfaces of the active area 202 and the word line insulative structures 120 proximal to an individual opening 112 may define a lower boundary (e.g., in the Z-direction) of the opening 112. The geometric configuration of an individual opening 112 may at least partially depend upon the shapes and dimensions of desired features (e.g., structures) to be later-formed within the opening 112. Additionally, the geometric configuration of an individual opening 112 may at least partially depend on the geometric configurations and positions of other features (e.g., the active areas 102, the STI structures 104, the word line insulative structure 120, the word lines 118) that neighbor the opening 112. In some embodiments, the openings 112 are formed to individually exhibit a substantially frustoconical shape. Individual openings 112 may be formed to exhibit substantially the same geometric configuration (e.g., substantially the same dimensions or substantially the same shape) as each other of the openings 112, or at least one of the openings 112 may be formed to exhibit a different geometric configuration (e.g., different dimension(s) and/or a different shape) than at least one other of the openings 112.

Still referring to FIG. 1B, following formation of the openings 112, the liner nitride 114 may be formed within the openings 112. The liner nitride 114 may be conformally formed to substantially extend (e.g., substantially continuously extend) over the exposed surfaces of the microelectronic device structure 100 within the openings 112, including surfaces of the first dielectric material 106, the second dielectric material 108, and the third dielectric material 110, the active area 102 proximal to the opening 112, and the word line insulative structures 120 adjacent to the active area 102. The liner nitride 114 may substantially conform to a topography defined by the sidewalls of the first dielectric material 106, the second dielectric material 108, and the third dielectric material 110 and upper facing surfaces of the active area 102 and the word line insulative structure 120 proximal to the opening 112. The liner nitride 114 may include a silicon nitride material, a silicon oxynitride material, a silicon carbon nitride material, or a silicon carboxynitride material. The liner nitride 114 may, for example, be a silicon nitride material. The liner nitride 114 may have substantially the same composition as the second dielectric material 108, or may have a different composition.

Following formation of the liner nitride 114, the liner 116 may be conformally formed within the opening 112 of the microelectronic device structure 100 on exposed surfaces of the liner nitride 114. The liner 116 and the liner nitride 114 may form a so-called “bilayer” liner in the opening 112. The liner 116 may extend (e.g., substantially continuously extend) over the exposed surfaces of the microelectronic device structure 100 and may partially fill (e.g., less than completely fill) the opening 112. The liner 116 may substantially conform to a topography defined by the liner nitride 114 and may extend over surfaces (e.g., top surfaces, sloped surfaces) of the liner nitride 114. The liner 116 may be formed of and include the silicon carbon or the doped silicon carbon material, such as SiC, silicon carbon oxide (SiC_{y}Oₓ), or silicon carbon nitride (SiCN_{y}), wherein an atomic percentage (at. %) of carbon within the liner 116 is within a range of from about 0.1 at. % to about 20 at. %, such as from about 6 at. % to about 15 at. %, from 8 at. % to about 15 at. %, from about 10 at. % to about 20 at. %, from about 10 at. % to about 15 at. %, or from about 8 at. % to about 10 at. %. The liner 116 may, for example, be formed by CVD, ALD, or other technique suitable for forming the liner 116 at a desired thickness and at a high degree of conformality. In some embodiments, the liner 116 is silicon carbon oxide where one or more of the carbon atoms of the silicon carbon oxide are bonded to the silicon atoms. In other embodiments, the liner 116 is silicon carbon nitride. The liner 116 may be formed at a temperature of from about 200° C. to about 700° C., such as from about 300° C. to about 600° C., or from about 375° C. to about 550° C.

A thickness of the liner 116 may at least partially depend on the desired dimension (e.g., width in the X- and/or Y-directions) of the features to be formed in the opening 112 during subsequent process acts. The liner 116 may be formed at a minimum thickness that provides a substantially continuous material over the exposed surfaces of the microelectronic device structure 100, such that the liner 116 may not include gaps, pinholes, etc. The liner 116 may be formed at a thickness of from about 1 nm to about 15 nm, such as from about 1 nm to about 10 nm, from about 1 nm to about 8 nm, from about 1 nm to about 7 nm, from about 3 nm to about 10 nm, or from about 3 nm to about 8 nm. By way of example only, the liner 116 may be about 1 nm thick, which reduces the width of the opening 112 by about 2 nm and may enable smaller features (e.g., smaller than the CD of the opening 112) to be formed, as described below. By forming the liner 116 at a high degree of conformality, the liner 116 may be substantially uniform in its thickness.

Referring next to FIG. 1C, the liner 116 (FIG. 1B) may be subjected to (e.g., exposed to) one or more treatment acts that change (e.g., reduce) the carbon content of desired portions of the liner 116. For instance, the one or more treatment acts may change the chemical composition of the exposed portions of the liner 116 compared to the composition of the liner 116 as initially formed. The treatment act may include exposing the liner 116 to a plasma 122 (e.g., an oxygen gas (O₂) plasma). For example, the oxygen atoms of the plasma 122 may replace the carbon atoms of the liner material, thus reducing the carbon content of the liner 116. The portions of the liner 116 exposed to the plasma 122 may be the portions of the liner 116 adjacent to (e.g., on) the horizontal surfaces of the liner nitride 114. For instance, the horizontally-oriented portions of the liner 116 may be exposed to the plasma 122, forming treated liner portions 124, while portions of the liner 116 on the sidewalls of the liner nitride 114 are not substantially exposed to the plasma 122, resulting in unexposed portions of the liner 116′. Following the plasma 122 treatment act, the treated liner portions 124 may exhibit a decreased amount of carbon relative to the unexposed portions (e.g., portions on the sidewalls of the liner nitride 114) of the liner 116′. By way of example only, the treated liner portions 124 may be substantially free of carbon, such that the treated liner portions 124 include no (e.g., 0 at. %) carbon. The unexposed portions of the liner 116′ may include substantially the same amount of carbon as the as-formed liner 116.

To prevent damage to the portions of the liner 116′ that are not oriented horizontally (e.g., the unexposed portions), the plasma 122 treatment act may be a highly directional plasma treatment act where the direction of the flow of ions is controlled (e.g., biased). A light bias may be used to selectively expose the horizontal portions of the liner 116 to the plasma 122. The horizontal portions of the liner 116 may be exposed to a greater concentration of ions of the plasma 122 than the portions of the liner 116 on the sidewalls of the liner nitride 114. The bias may range from about 300 V to about 700 V, such as about 400 V or about 600 V. Therefore, only the treated liner portions 124 may be reduced in carbon content following the plasma 122 treatment act. The unexposed portions of the liner 116′ may remain substantially unaffected in carbon content following the plasma 122 treatment act and exhibit a material composition that is substantially the same as the material composition of the liner 116 as initially formed. The portions (e.g., the treated liner portions 124) affected by the plasma 122 treatment may exhibit a material composition that is different from the material composition of the liner 116 as initially formed.

The plasma 122 may be a reducing plasma that includes, but is not limited to, an O₂ plasma, an O₂/hydrogen gas (H₂)/nitrogen gas (N₂) plasma, an H₂/N₂ plasma, or an O₂/fluorocarbon plasma. The plasma 122 may also include an inert gas, such as argon. In some embodiments, the plasma 122 includes 100 weight percent (wt %) O₂. Process conditions for the plasma 122 treatment act, such as time, RF power, exhaust power, gas mixture, and flow rate may be chosen depending on the composition of the plasma 122 utilized for the treatment act and the desired directionality of the plasma 122 treatment act. In addition, the shape and dimensions of the opening 112 may determine the process conditions utilized during the plasma 122 treatment act. For instance, an opening with a smaller CD (e.g., width in the X- and/or Y-directions) than another opening with a larger CD may utilize increased RF power, increased exhaust power, and an increased flow rate to treat the horizontal portions of the liner 116. The thickness of the liner 116 may determine, in part, the process conditions utilized during the plasma 122 treatment act. A liner 116 with a greater thickness may use increased RF power, increased exhaust power, and an increased flow rate to achieve the same degree of treatment of the horizontal portions of the liner 116.

As a result of the plasma 122 treatment act, the treated liner portions 124 may exhibit a reduced carbon content compared to the remaining (e.g., untreated) portions of the liner 116′. After conducting the plasma 122 treatment, the treated liner portions 124 may contain substantially no carbon. Exposing the liner 116 (FIG. 1B) to the plasma 122 may decrease the carbon content in the horizontally-oriented portions of the liner 116 and may increase the oxygen content therein. If, for example, the liner 116 is formed from silicon carbon oxide, the portions of the silicon carbon oxide exposed to the plasma 122 may be converted to a silicon oxide (SiOₓ) material by the plasma 122 treatment. The SiOₓ material of the treated liner portions 124 may be selectively removable (e.g., selectively etchable) relative to the silicon carbon oxide of the untreated portions of the liner 116′. The different chemical compositions of the treated liner portions 124 and the remaining portions of the liner 116′ may be used to provide etch selectivity during subsequent process acts.

Referring next to FIG. 1D, the treated liner portions 124 and portions of the liner nitride 114 (FIG. 1C) underlying (e.g., in the Z-direction) the treated liner portions 124 may be selectively removed from the microelectronic device structure 100. For instance, the treated liner portions 124 and portions of the liner nitride 114 may be removed. In this processing act, the portions of the liner 116′ may remain in place, and other portions of the liner nitride 114′ covered by the portions of the liner 116′ (e.g., portions of the liner nitride 114 on the sidewalls of the first dielectric material 106, the second dielectric material 108, and the third dielectric material 110 and on upper facing surfaces of the word line insulative structure 120) remain in place. The treated liner portions 124 and portions of the liner nitride 114 may be removed (e.g., etched) by a selective etch (e.g., an isotropic etch) process, such as a wet etch process, or a vapor etch process. By way of non-limiting example, the treated liner portions 124 and portions of the liner nitride 114 may be removed by a wet etch process. By using a highly selective wet etch process, the treated liner portions 124 and underlying portions of the liner nitride 114 may be removed from the opening 112 (FIG. 1C) to form an opening 112′.

The portions of the liner 116′ remaining in the opening 112′ may exhibit sloped sidewalls or substantially vertical sidewalls following the wet etch process. At locations where the horizontal portions of the liner nitride 114 and the liner 116 were removed and/or the liner nitride 114′ remains in the opening 112′, the liner nitride 114′ and the liner 116′ exhibit substantially vertical sidewalls (e.g., an angle of approximately 90 degrees). The substantially vertical sidewalls of the liner nitride 114′ and the liner 116′ may be proximal to locations previously occupied by the treated liner portions 124. The conditions of the wet etch process used to remove the treated liner portions 124 may not remove untreated portions of the liner 116′. Additionally, the conditions of the wet etch process used to remove the treated liner portions 124 may not remove portions of the liner nitride 114′ covered by the untreated portions of the liner 116′, which may thus be protected from the wet etch chemistry. The active area 102 exposed through the opening 112′ may be substantially unaffected by the etch chemistry and etch conditions used, so that exposed upper surfaces of the active area 102 may define a lower boundary of the opening 112′ following the wet etch process.

By way of non-limiting example, if the liner 116 (FIG. 1B) is formed from a silicon carbon oxide material, the treated liner portions 124 may be selectively removed using an aqueous hydrogen fluoride (HF) solution. The etch chemistry and etch conditions may be selected to substantially remove the treated liner portions 124 and portions of the liner 116 underlying the treated liner portions 124, while the liner 116′ remains on the sidewalls of the liner nitride 114′ in the opening 112. While the liner nitride 114 and the liner 116 in FIG. 1B are shown as being substantially continuous materials, the liner nitride 114′ and the liner 116′ in FIG. 1D may be discontinuous (e.g., segmented) following the wet etch process.

In the methods according to embodiments of the disclosure, substantially vertical sidewalls of the word line insulative structures 120 or other structures at horizontal boundaries of the opening 112′ and consistent horizontal spacing between neighboring features (e.g., between a later-formed contact structure 128′ (FIG. 1F; FIG. 1G) and other active areas 102, other conductive materials, or other contacts) may be formed. In addition, the opening 112′ resulting from the wet etch process may exhibit a substantially similar height H₁ as the height H₁ of the opening 112 (FIG. 1B), such as between about 95% and about 105% of the height H₁ of the opening 112. Thus, the methods according to embodiments of the disclosure may provide better control of the height H₁ of the opening 112′ in comparison to conventional methods. As a result, methods disclosed herein may provide for removal of the treated liner portion 124 without damaging exposed materials of the microelectronic device structure 100, such as the active area 102 exposed through the opening 112′.

In contrast, if a conventional dry etch process were used to remove a portion of a silicon nitride liner during a similar stage of fabrication as that shown in FIG. 1D of a conventional microelectronic device structure, the remaining liner may exhibit rounded corners. Additionally, if portions of a liner (e.g., similar to the liner nitride 114) of a conventional microelectronic device structure were removed by a conventional dry etch process, the active area below the opening may be recessed downward (e.g., in the Z-direction) during the dry etch process, which may expose portions of the word line insulative structures to the dry etch process. Thus exposed, the dry etch process may result in partial removal of the word line insulative structure and horizontal enlargement of the individual openings (e.g., at an elevation of the word line insulative structure). A later-formed conductive material and/or a contact (e.g., bit line contact) in such an enlarged opening may be insufficiently and/or inconsistently horizontally separated (e.g., in the X- and/or Y-directions) from adjacent features (e.g., other active areas, other conductive materials, other contacts) of the conventional microelectronic device structure, and may thus exhibit undesirable electrical performance compared to a conductive material and/or a contact device sufficiently and consistently horizontally separated from adjacent features. Additionally, in the case of a conventional dry etch process, the word line insulative structure may exhibit a sloped profile (e.g., shoulders) at horizontal boundaries of an opening corresponding to the opening 112′.

Referring to FIG. 1E, the active area 102 exposed through the opening 112′ may be partially removed to recess the active area 102 downward (e.g., in the Z-direction) to a predetermined vertical elevation and to extend the lower boundary of the opening 112′ downward. Thereafter, a conductive material 126 may be formed in the opening 112′, adjacent to (e.g., over, directly over) the recessed active area 102. The conductive material 126 may at least partially fill the opening 112′. Excess conductive material 126 may be removed by conventional techniques to recess the conductive material 126 in the opening 112′ to a desired vertical elevation (e.g., in the Z-direction). The conductive material 126 may extend vertically (e.g., in the Z-direction) from the horizontal (e.g., top surface) surface of the recessed active area 102 to a predetermined height (e.g., dimension in the Z-direction) within the opening 112′ above the active areas 102. The conductive material 126 may extend horizontally (e.g., in the X- and Y-directions) between sidewalls of the word line insulative structure 120 in the opening 112′. The conductive material 126 may be formed of and include a polysilicon or a metal material.

Following formation of the conductive material 126, a contact structure material 128 may be formed within the opening 112′ vertically adjacent to (e.g., over, in the Z-direction) the conductive material 126. The contact structure material 128 may extend vertically (e.g., in the Z-direction) from the horizontal surface (e.g., top surface) of the conductive material 126 to a predetermined height (e.g., in the Z-direction) at least as high as the vertical elevation of an upper surface of the second dielectric material 108. The contact structure material 128 may substantially fill portions of the opening 112′ remaining unfilled by the liner 116′, the liner nitride 114′, and the conductive material 126 to at least such a vertical elevation. The contact structure material 128 may be formed of and include at least one conductive material. The width of the contact structure material 128 (e.g., dimension in the Y-direction) may be substantially equal to the reduced width W₂ (FIG. 1D) of the opening 112′. Therefore, the contact structure material 128 may exhibit a smaller width than the width W₁ of the opening 112 (FIG. 1B) as initially formed. By conducting the plasma treatment act followed by the wet etch process or the vapor etch process, no dry etch process is used to form the openings 112 in which the conductive material 126 and the contact structure material 128 are subsequently formed. Therefore, the width of the conductive material 126 and the contact structure material 128 may be less than the width of the openings 112.

Following formation of the contact structure material 128, the third dielectric material 110 and upper portions of the liner 116′, the liner nitride 114′ (FIG. 1D), and the contact structure material 128 substantially vertically aligned with the third dielectric material 110 may be removed. Additionally, an upper portion (e.g., in the Z-direction) of the second dielectric material 108 and upper portions of the liner 116′, the liner nitride 114′, and the contact structure material 128 substantially vertically aligned with the upper portion of the second dielectric material 108 may be removed. Removing upper portions of the liner 116′ and the liner nitride 114′ may result in a liner 116″ and a liner nitride 114″, respectively. The upper portion (e.g., in the Z-direction) of the second dielectric material 108 may be removed along with removal of the third dielectric material 110 and/or portions of the liner 116′, the liner nitride 114′, and the contact structure material 128 in a single processing act, or the upper portion of the second dielectric material 108 may be removed through an additional material removal process. Removal of the third dielectric material 110 and upper portions of the liner 116′, the liner nitride 114′, the contact structure material 128, and the second dielectric material 108 may leave respective upper surfaces (e.g., in the Z-direction) of the second dielectric material 108, the liner 116″, the liner nitride 114″, and the contact structure material 128 substantially coplanar with one another.

Still referring to FIG. 1E, a digit line material 130 may be formed vertically adjacent to (e.g., over, in the Z-direction) the second dielectric material 108, the liner 116″, the liner nitride 114″, and the contact structure material 128. The digit line material 130 may contact (e.g., physically contact, electrically contact) the contact structure material 128. The digit line material 130 may be formed of at least one conductive material. The conductive material of the digit line material 130 may be the same as or different than the conductive material of the contact structure material 128.

A digit line cap 132 (e.g., a dielectric material) may be formed on or over the contact structure material 128. The digit line cap 132 may substantially horizontally extend over and cover the contact structure material 128. The digit line cap 132 may be formed of and include at least one dielectric material that may substantially mitigate oxidation of the contact structure material 128. For example, the digit line cap 132 may be formed of and include at least one dielectric nitride material (e.g., SiN_{y}, such as Si₃N₄).

Referring to FIG. 1F, portions of the digit line cap 132, the digit line material 130, the contact structure material 128, the second dielectric material 108, the first dielectric material 106, the contact structure material 128, the liner 116″, and the liner nitride 114″ (FIG. 1E) may be removed to form a repeating horizontal pattern of openings comprising digit line openings 134, spaced from one another in the Y-direction. The liner 116″ and the liner nitride 114″ may be substantially completely removed in the perspective shown in FIG. 1F. The digit line openings 134 may vertically extend (e.g., in the Z-direction) completely through the digit line cap 132, the contact structure material 128, the second dielectric material 108, and the first dielectric material 106 to expose underlying portions of the active areas 102 and the word line insulative structures 120. In forming the digit line openings 134, the remaining portions of the digit line material 130 may become discontinuous from each other, individually forming digit line structures 136, and the contact structure material 128 may be formed into a contact structure 128′. A width of an upper portion of the contact structure 128′ may be narrower than a width of a lower portion of the contact structure 128′. Therefore, the width of the upper portion of the contact structure material 128 may be less than the width of the lower portion, which is substantially equal to the reduced width W₂ of the opening 112′. A fill material (not shown) may subsequently be formed in the digit line openings 134.

FIG. 1G is a simplified partial cross-sectional view showing an embodiments of a method of forming the microelectronic device structure 100 of FIG. 1A, wherein the dashed line B-B (FIG. 1A) corresponds to the longitudinal cross section of the microelectronic device structure 100 depicted in FIG. 1G. FIG. 1G depicts the microelectronic device structure 100 at the process stage depicted in FIG. 1F. As shown in FIG. 1G, the digit line structures 136 individually extend substantially linearly in the X-direction. As shown in the perspective of FIG. 1G, the liner 116″ and the liner nitride 114″ may be present adjacent to the contact structure 128′.

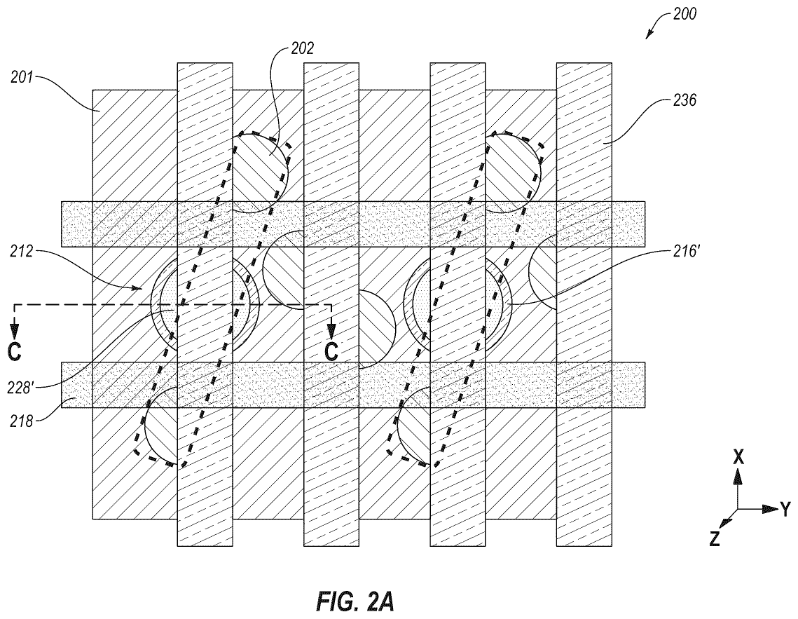

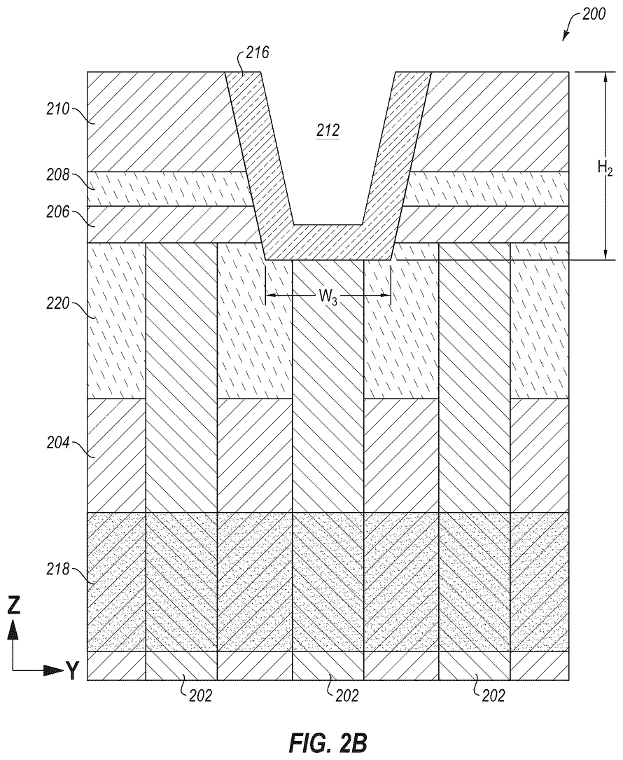

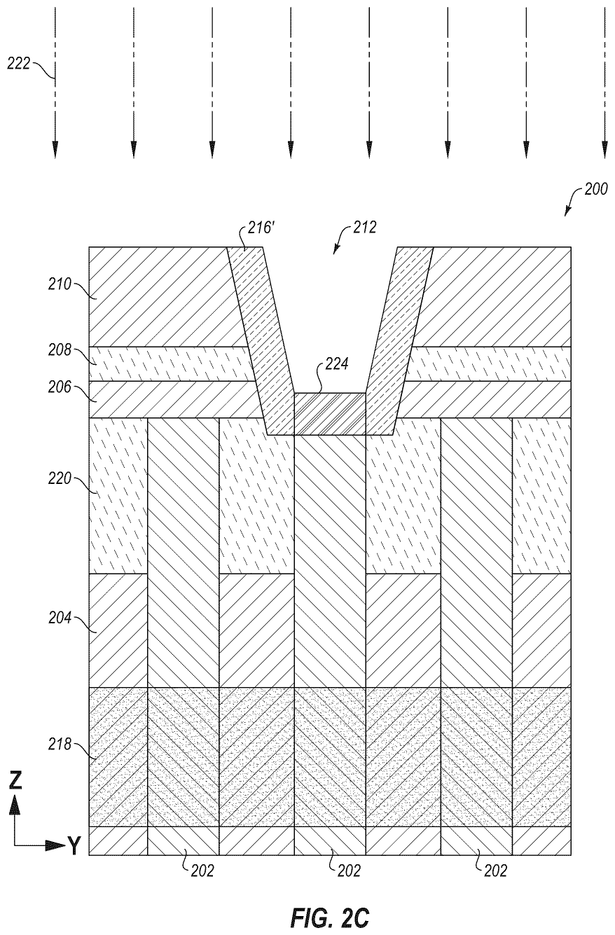

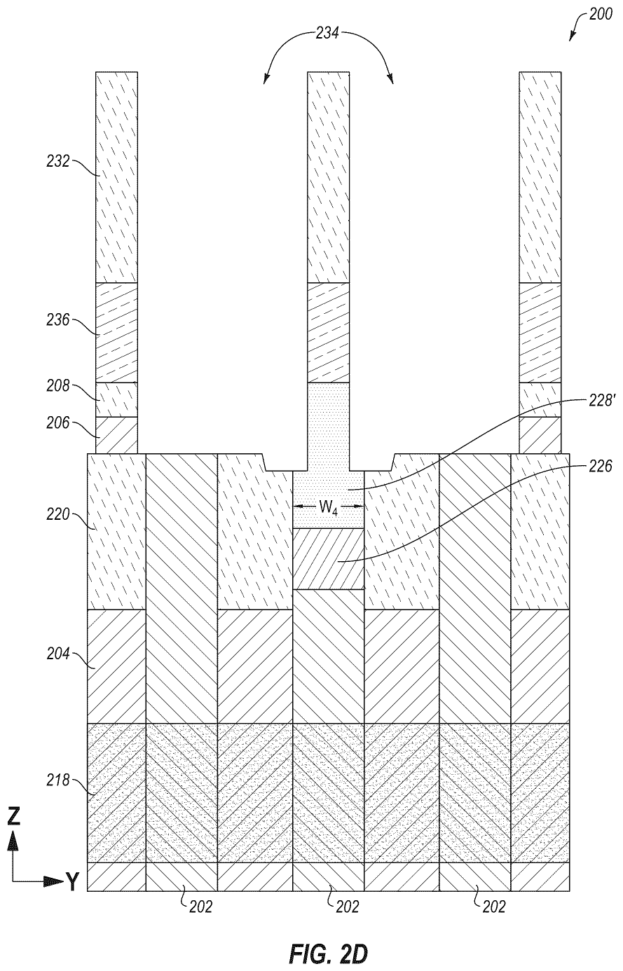

FIG. 2A illustrates a microelectronic device structure 200 (e.g., a microelectronic device; a semiconductor device; a memory device, such as a DRAM device). The microelectronic device structure 200 may include active areas 202, openings 212, liner 216′, word lines 218 (e.g., access line structures, access lines), contact structures 228′ (e.g., digit line contacts), and digit line structures 236. The microelectronic device structure 200 shown in FIG. 2A has been subjected to previous fabrication acts to form these components of a microelectronic device structure 200 on a base material 201, as is described in further detail with reference to FIGS. 2B through 2D. As shown in FIG. 2A, the microelectronic device structure 200 comprises multiple active areas 202, horizontally offset (e.g., in the X- and Y-directions) from the openings 212. Individual active areas 202 are horizontally offset in the Y-direction from adjacent digit line structures 236, which extend substantially parallel to one another in the X-direction. The openings 212 may comprise filled openings. At the processing stage shown in FIG. 2A, an individual contact structure 228′ is concentrically positioned within a corresponding liner 216′ and the individual liner 216′ is concentrically positioned within the horizontal area of a corresponding opening 212. The openings 212 are horizontally interposed (e.g., in the X-direction) between adjacent word lines 218, which extend substantially parallel to one another in the Y-direction. The word lines 218 are horizontally adjacent (e.g., in the X-direction) to the active areas 202 and extend perpendicular to the digit line structures 236.

FIGS. 2B through 2D are simplified partial cross-sectional views showing embodiments of a method of forming the microelectronic device structure 200 of FIG. 2A, where dashed line C-C corresponds to the longitudinal cross section of the microelectronic device structure 200 depicted in FIGS. 2B through 2D. The microelectronic device structure 200 may be formed using processing acts similar to those described above with respect to FIGS. 1B through 1G, but without forming a liner nitride (e.g., liner nitride 114) in an opening (e.g., opening 112, opening 212). At the processing stage depicted in FIG. 2B, the microelectronic device structure 200 comprises shallow trench isolation (STI) structures 204, a first dielectric material 206, a second dielectric material 208, a third dielectric material 210, word line insulative structures 220 (e.g., a word line cap), active areas 202, and a word line 218. The active areas 202, STI structures 204, word line 218, and word line insulative structures 220 may be formed by conventional techniques. The word lines 218 may be horizontally adjacent (e.g., in the X-direction) to the active areas 202 and horizontally adjacent (e.g., in the X- and Y-directions) to the STI structures 204. The word line insulative structures 220 may be formed to be vertically positioned (e.g., in the Z-direction) above the word lines 218. In addition, the microelectronic device structure 200 may include the first dielectric material 206 vertically overlying (e.g., on, directly on, directly contacting) the active areas 202 and the word line insulative structures 220, the second dielectric material 208 vertically overlying the first dielectric material 206, and the third dielectric material 210 vertically overlying the second dielectric material 208.

The microelectronic device structure 200 at the process stage shown in FIG. 2B may be formed by conventional techniques. The active areas 202 may be formed of silicon, such as a monocrystalline silicon, a doped monocrystalline silicon, or a polysilicon and may be isolated from one another by the STI structures 204, which may be formed of a nitride material (e.g., a silicon nitride (SiN), an oxynitride). By way of example only, the active areas 202 may be formed of silicon and the STI structures 204 may be formed of silicon nitride. The first dielectric material 206 and the third dielectric material 210 may each be formed of the same oxide material, or may be formed of different oxide materials. The first dielectric material 206 and the third dielectric material 210 may include, but are not limited to, a silicon oxide material. The second dielectric material 208 may be formed of a material that is selectively etchable relative to one or more other dielectric materials used during the fabrication process. The second dielectric material 208 may include, but is not limited to, a silicon nitride material, a silicon oxynitride material, a silicon carbon nitride material, or a silicon carboxynitride material. The second dielectric material 208 may, for example, comprise a silicon nitride material.

The microelectronic device structure 200 may include an opening 212 extending downward (e.g., in the Z-direction) into the first dielectric material 206, the second dielectric material 208, the third dielectric material 210, at least one of the active areas 202, and the word line insulative structures 220. The opening 212 may be formed by removing portions of material from the third dielectric material 210 to at least one of the active areas 202 and the word line insulative structures 220. The opening 212 may be formed by conventional techniques. Dimensions of the opening 212 include a width W₃ in the Y-direction and a height H₂ in the Z-direction. The width W₃ of the opening 212 may be defined at the lower boundary (e.g., in the Z-direction) of the opening 212. The opening 212 may have horizontal boundaries at least partially defined by opposing side surfaces (e.g., opposing sidewalls) of the first dielectric material 206, the second dielectric material 208, the third dielectric material 210, and the word line insulative structures 220. The sidewalls of the first dielectric material 206, the second dielectric material 208, the third dielectric material 210, and the word line insulative structures 220 defining the opening 212 may be vertical, substantially vertical, or sloped. Upper surfaces of an active area 202 proximal to (e.g., directly underlying) the opening 212 may be vertically recessed relative to other active areas 202. Upper surfaces of the active area 202 and the word line insulative structures 220 proximal to the opening 212 may define a lower boundary (e.g., in the Z-direction) of the opening 212. The geometric configuration of an individual opening 212 may at least partially depend upon the shapes and dimensions of desired features (e.g., structures) to be later-formed within the opening 212. Additionally, the geometric configuration of an individual opening 212 may at least partially depend on the geometric configurations and positions of other features (e.g., the active areas 202, the STI structures 204, the word line insulative structures 220, the word lines 218) that neighbor the opening 212. In some embodiments, the openings 212 are formed to individually exhibit a substantially conical shape. Individual openings 212 may be formed to exhibit substantially the geometric configuration (e.g., substantially the same dimensions or substantially the same shape) as each other of the openings 212, or at least one of the openings 212 may be formed to exhibit a different geometric configuration (e.g., different dimension(s) and/or a different shape) than at least one other of the openings 212.

Still referring to FIG. 2B, following formation of the openings 212, a liner 216 may be formed within the opening 112 of the microelectronic device structure 100 on exposed surfaces (e.g., the sidewalls) of the first dielectric material 206, the second dielectric material 208, the third dielectric material 210, and the word line insulative structures 220 defining the opening 212. The liner 216 may extend (e.g., continuously extend) over the exposed surfaces of the microelectronic device structure 200 and may partially fill (e.g., less than completely fill) the opening 212. The liner 216 may substantially conform to a topography defined by the sidewalls of the first dielectric material 206, the second dielectric material 208, the third dielectric material 210 and the word line insulative structures 220 and upper facing surfaces of the active area 202 and the word line insulative structures 220 proximal to the opening 212. The liner 216 may be formed of and include the silicon carbon material or the doped silicon carbon material as described above with respect to the liner 116. The liner 116 may be formed at a temperature of from about 200° C. to about 700° C., such as from about 300° C. to about 600° C., or from about 375° C. to about 550° C.

A thickness of the liner 216 may at least partially depend on the desired dimension (e.g., width in the X- and/or Y-directions) of the features to be formed in the opening 212 during subsequent process acts. The liner 216 may be formed at a minimum thickness that provides a substantially continuous material over the exposed surfaces of the microelectronic device structure 200, such that the liner 216 may not include gaps, pinholes, etc. The liner 216 may be formed at a thickness from about 1 nm to about 15 nm, such as from about 1 nm to about 10 nm, from about 1 nm to about 8 nm, from about 1 nm to about 7 nm, from about 3 nm to about 10 nm, or from about 3 nm to about 8 nm. By way of example only, the liner 216 may be about 1 nm thick, which reduces the width of the opening 212 by about 2 nm and may enable smaller features (e.g., smaller than the CD of the openings 212) to be formed, as described below. By forming the liner 216 at a high degree of conformality, the liner 216 may be substantially uniform in its thickness.

As depicted in FIG. 2B, the microelectronic device structure 200 may have a structure similar to the microelectronic device structure 100 (FIG. 1B), but without a liner nitride (e.g., liner nitride 114) between the liner 216 and the sidewalls of the first dielectric material 206, the second dielectric material 208, the third dielectric material 210, and the word line insulative structure 220 and upper facing surfaces of the active area 202 and the word line insulative structure 220 underlying the opening 212.

Referring to FIG. 2C, the liner 216 (FIG. 2B) may be subjected to (e.g., exposed to) one or more treatment acts that change (e.g., reduce) the carbon content of desired portions of the liner 216, changing the chemical composition of the portions of the liner 216 compared to the composition of the liner 216 as initially formed. The treatment act may include exposing the liner 216 to a plasma 222 treatment act (e.g., an oxygen gas (O₂) plasma treatment act). For example, the oxygen atoms of the plasma 222 treatment replace the carbon atoms of the liner material, therefore reducing the carbon content of the liner 216. The portions of the liner 216 exposed to the plasma 222 may be the portions of the liner 216 adjacent to (e.g., on) the horizontal surfaces of the word line insulative structure 220 and the horizontal surfaces of the active areas 102. For instance, the horizontally-oriented portions of the liner 216 may be exposed to the plasma 222, forming treated liner portions 224, while portions of the liner 216 on the sidewalls of the first dielectric material 206, the second dielectric material 208, the third dielectric material 210, and the word line insulative structures 220 are not substantially exposed to the plasma 222, resulting in unexposed portions of the liner 216′. Following the plasma 222 treatment act, the treated liner portions 224 may exhibit a decreased amount of carbon relative to the unexposed portions (e.g., portions on the sidewalls of the first dielectric material 206, the second dielectric material 208, the third dielectric material 210, and the word line insulative structures 220) of the liner 216′. By way of example only, the treated liner portions 224 may be substantially free of carbon, such that the treated liner portions 224 include no (e.g., 0 at. %) carbon. The plasma 222 treatment act may be carried out under conditions and parameters similar to the plasma 122 treatment act described above with respect to FIG. 1C. As a result of the plasma 222 treatment act, the treated liner portions 224 may exhibit a composition and characteristics similar to the treated liner portions 124 described above with respect to FIG. 1C.

Referring next to FIG. 2D, the treated liner portions 224 (FIG. 2C) may be selectively removed from the microelectronic device structure 200. For instance, the treated liner portions 224 may be removed while the portions of the liner 216′ remain in place. The treated liner portions 224 may be removed (e.g., etched) by a selective etch (e.g., an isotropic etch) process, such as a wet etch process, or a vapor etch process. By way of non-limiting example, the treated liner portions 224 may be removed by a wet etch process. By using a highly selective, wet etch process, the treated liner portions 224 may be removed from the opening 212 (FIG. 2C).

The conditions of the wet etch process used to remove the treated liner portions 224 may not substantially remove portions of the first dielectric material 206, the second dielectric material 208, the third dielectric material 210 and the untreated portions of the liner 216′. The active areas 202 exposed through the opening 212 may be substantially unaffected by the etch chemistry and etch conditions used, so that upper surfaces of the active area 202 may define a lower boundary of the opening 212 following the wet etch process.

By way of non-limiting example, if the liner 216 (FIG. 2B) is formed from a silicon carbon oxide material, the treated liner portions 224 may be selectively removed using an aqueous hydrogen fluoride (HF) solution. The etch chemistry and etch conditions may be selected to substantially remove the treated liner portions 224, while the liner 216′ remains on the sidewalls of the first dielectric material 206, the second dielectric material 208, the third dielectric material 210, and the word line insulative structures 220 in the opening. While the liner 216 in FIG. 2B is shown as being a substantially continuous material, the liner 216′ may be discontinuous (e.g., segmented) following the wet etch process.

If a conventional dry etch process were used to remove a portion of a liner in an opening and/or portions of the first dielectric material 206, the second dielectric material 208, the third dielectric material 210, the active area 202 exposed through the opening, and/or the word line insulative structures 220 proximate to the opening during a similar stage of fabrication of a conventional microelectronic device structure, the remaining portions may exhibit rounded corners. Further, the portions of the active area 202 exposed through the opening may be recessed downward (e.g., in the Z-direction) during the conventional dry etch process, which may expose portions of the word line insulative structures 220 to the dry etch process. Thus exposed, the dry etch process may result in partial removal of the word line insulative structures 220 and horizontal enlargement of the individual openings (e.g., at an elevation of the word line insulative structures 220). A later-formed conductive material and/or a contact in such an enlarged opening may be insufficiently and/or non-uniformly horizontally separated from adjacent features (e.g., other active areas 202, other conductive materials, other contacts) of the microelectronic device structure 200, and may thus exhibit undesirable electrical performance compared to a conductive material and/or a contact device sufficiently spaced from adjacent features. Additionally, in the case of a conventional dry etch process, the word line insulative structures 220 may exhibit a sloped profile (e.g., shoulders) at horizontal boundaries of the opening 212.

In contrast, the methods according to embodiments of the disclosure may result in substantially vertical sidewalls of the word line insulative structures 220 or other structures positioned at horizontal boundaries of the opening 212 (FIG. 2B) and consistent (e.g., uniform) horizontal spacing between neighboring features (e.g., between a contact structure 228′ and other active areas 202, other conductive materials, or other contacts). In addition, the opening 212 resulting from the wet etch process may exhibit a substantially similar height as the height H₂ of the opening 212 (FIG. 2A), such as between about 95% and about 105% of the height H₂ of the opening 212. Thus, the methods according to embodiments of the disclosure may provide better control of the height H₂ of the opening 212 in comparison to conventional methods. As a result, methods disclosed herein may provide for removal of the treated liner portions 224 without damaging exposed materials of the microelectronic device structure 200, such as the active area 202 exposed through the opening 212.

Still referring to FIG. 2D, the active area 202 exposed through the opening 212 (FIG. 2C) may be partially removed to recess the active area 202 downward (e.g., in the Z-direction) to a predetermined vertical elevation and to extend the lower boundary of the opening downward. Thereafter, a conductive material 226 may be formed in the opening, adjacent to (e.g., over, directly over) the recessed active area 202. The conductive material 226 may at least partially fill the opening. Excess conductive material 226 may be removed by conventional techniques to recess the conductive material 226 in the opening to a desired vertical elevation (e.g., in the Z-direction). The conductive material 226 may extend vertically (e.g., in the Z-direction) from the horizontal (e.g., top surface) surface of the recessed active area 202 to a predetermined height (e.g., dimension in the Z-direction) within the opening above the active area 202. The conductive material 226 may extend horizontally (e.g., in the X-direction) between sidewalls of the word line insulative structures 220 in the opening. The conductive material 226 may be formed of and include a polysilicon or a metal material.

Following formation of the conductive material 226, a contact structure material (not shown as initially formed) may be formed within the opening vertically adjacent to (e.g., over, in the Z-direction) the conductive material 226. The contact structure material may extend vertically (e.g., in the Z-direction) from the horizontal (e.g., top surface) surface of the conductive material 226 to a predetermined height (e.g., in the Z-direction) at least as high as the vertical elevation of an upper surface of the second dielectric material 208. The contact structure material may substantially fill portions of the opening remaining unfilled by the liner 216′ (FIG. 2C) and the conductive material 226 to such a vertical elevation. The contact structure material may be formed of and include at least one conductive material. The width W₄ of the contact structure material (e.g., dimension in the Y-direction) may be smaller than the width W₃ of the opening 212 (FIG. 2B).

Following formation of the contact structure material, the third dielectric material 210 and upper portions of the liner 216′ (FIG. 2C) and the contact structure material that are substantially vertically aligned with the third dielectric material 210 may be removed. Additionally, an upper portion (e.g., in the Z-direction) of the second dielectric material 208 and upper portions of the liner 216′ and the contact structure material that are substantially vertically aligned with the upper portion of the second dielectric material 208 may be removed. The upper portion (e.g., in the Z-direction) of the second dielectric material 208 may be removed along with removal of the third dielectric material 210 and/or portions of the liner 216′ and the contact structure material (e.g., using a single processing act), or the upper portion of the second dielectric material 208 may be removed through an additional material removal process. Removal of the third dielectric material 210 and upper portions of the liner 216′, the contact structure material, and the second dielectric material 208 may leave respective upper surfaces (e.g., in the Z-direction) of the second dielectric material 208, the liner 216′, and the contact structure material substantially coplanar with one another.

Still referring to FIG. 2D, a digit line material may be formed vertically adjacent to (e.g., over) the second dielectric material 208, the liner 216′, and the contact structure material. The digit line material may contact (e.g., physically contact, electrically contact) the contact structure material. The digit line material may be formed of at least one conductive material. The conductive material of the digit line material may be the same as or different than the conductive material of the contact structure material.

A digit line cap 232 (e.g., a dielectric material) may be formed on or over the contact structure material and the digit line material. The digit line cap 232 may substantially horizontally extend over and cover the contact structure material. The digit line cap 232 may be formed of and include at least one dielectric material that may substantially mitigate oxidation of the contact structure material. For example, the digit line cap 232 may be formed of and include at least one dielectric nitride material (e.g., SiN_{y}, such as Si₃N₄). Thereafter, portions of the digit line cap 232, the digit line material, the contact structure material, the second dielectric material 208, the first dielectric material 206, and the liner 216′ (FIG. 2C) may be removed to form a repeating horizontal pattern of openings comprising digit line openings 234, separated from one another in the Y-direction. The digit line openings 234 may vertically extend (e.g., in the Z-direction) completely through the digit line cap 232, the contact structure material, the second dielectric material 208, and the first dielectric material 206 to expose underlying portions of the active areas 202 and the word line insulative structures 220. In forming the digit line openings 234, the remaining portions of the digit line material may become discontinuous from each other, individually forming digit line structures 236, and the contact structure material may be formed into contact structures 228′. Similar to the microelectronic device structure 100 (FIG. 1G), the digit line structures 236 of the microelectronic device structure 200 may individually extend substantially linearly in the X-direction. The digit line openings 234 may comprise filled or unfilled openings.

A microelectronic device structure formed according to embodiments of the disclosure (e.g., microelectronic device structure 100, microelectronic device structure 200) may exhibit certain advantages in comparison to a microelectronic device structure formed using conventional methods. For example, the use of the plasma treatment act and the wet etch act may produce desired profiles of the active areas 102, 202 and/or word line insulative structures 120, 220 proximal to the openings 112′, 212 compared to conventional dry etch processes, which may result in a desired widths (e.g., in the X- and/or Y-directions) of the conductive materials 126, 226 and the contact structures 128′, 228′ and desired horizontal separation therebetween. As a result, the resulting microelectronic device structure 100, 200 including the conductive materials 126, 226 and the contact structures 128′, 228′ may exhibit improved electrical performance, including improved contact resistance properties and reduced shorting, compared to a microelectronic device structure formed using a conventional dry etch process.

Accordingly, a microelectronic device is disclosed and comprises active areas, shallow trench isolation structures adjacent to the active areas, word lines adjacent to the shallow trench isolation structures, word line insulative structures adjacent to the word lines, and a dielectric stack over the active areas on a base material. A first conductive material is vertically adjacent to an active area of the active areas and is between laterally adjacent word line insulative structures in a first horizontal direction. A second conductive material is vertically adjacent to the first conductive material, is between the laterally adjacent word line insulative structures, and between laterally adjacent portions of the dielectric stack in the first horizontal direction. The silicon carbon material is on sidewalls of the dielectric stack. A digit line is vertically adjacent to the second conductive material and to the dielectric stack, and is between laterally adjacent digit line openings in a second horizontal direction substantially orthogonal to the first horizontal direction.

Additionally, a microelectronic device is disclosed and comprises active areas on a base material, shallow trench isolation structures adjacent to the active areas, word lines adjacent to the shallow trench isolation structures, word line insulative structures adjacent to the word lines, and a dielectric stack over the active areas. A conductive material is vertically adjacent to an active area of the active areas and is between laterally adjacent word line insulative structures in a first horizontal direction. A contact structure is vertically adjacent to the conductive material and between laterally adjacent word line insulative structures in the first horizontal direction. An upper portion of the contact structure exhibits a narrower width than a lower portion of the contact structure. A silicon carbon material is on sidewalls of the dielectric stack and an upper surface of the contact structure is substantially coplanar with an upper surface of the silicon carbon material and an upper surface of the dielectric stack. A digit line is vertically adjacent to the contact structure and to the dielectric stack in a second horizontal direction substantially orthogonal to the first horizontal direction. A width of the digit line is substantially equal to the width of the upper portion of the contact structure.

Additionally, a method of forming a microelectronic device is disclosed and comprises forming openings in a dielectric stack, the openings defined by sidewalls of the dielectric stack and upper surfaces of word line insulative structures and active areas. A silicon carbon material is formed on the sidewalls of the dielectric stack and on the word line insulative structures and the active areas. The silicon carbon material is exposed to a plasma, a horizontal portion of the silicon carbon material on the word line insulative structures and active areas exposed to a greater concentration of ions of the plasma than a portion of the silicon carbon material on the sidewalls of the dielectric stack. The horizontal portion of the silicon carbon material on the word line insulative structures and active areas is removed without substantially removing the portion of the silicon carbon material on the sidewalls of the dielectric stack. A portion of the active area exposed between the portion of the silicon carbon material on the sidewalls of the dielectric stack is removed. One or more conductive materials are formed vertically adjacent to the active area.

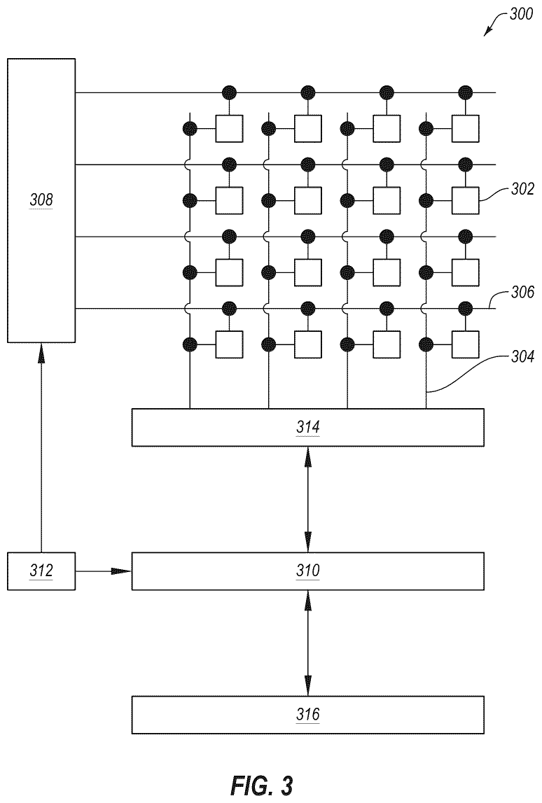

A microelectronic device structure (e.g., the microelectronic device structures 100, 200 previously described with reference to FIGS. 1A through 1G and 2A through 2D) may be subjected to additional processing acts to form a microelectronic device 300 containing one of more of the microelectronic device structures 100, 200, as shown in FIG. 3. Such additional processing acts may employ conventional processes and conventional processing equipment. The microelectronic device 300 may include, for example, one or more of the microelectronic device structures 100, 200 previously described herein. FIG. 3 shows a functional block diagram of the microelectronic device 300 (e.g., a DRAM device, a memory device), in accordance with embodiments of the disclosure. As shown in FIG. 3, the microelectronic device 300 includes memory cells 302 that may include one or more of the microelectronic device structures 100, 200, digit lines 304 (e.g., the digit line structures 136, 236 of microelectronic device structures 100, 200, respectively, previously described with reference to FIGS. 1F, 1G, and 2D), word lines 306 (e.g., the word lines 118, 218 of microelectronic device structures 100, 200, respectively, previously described with reference to FIGS. 1A through 2D), a row decoder 308, a column decoder 310, a memory controller 312, a sense device 314, and an input/output device 316.

The memory cells 302 of the microelectronic device 300 may be programmable to at least two different logic states (e.g., logic 0 and logic 1). Each memory cell 302 may individually include a capacitor and a transistor. The capacitor stores a charge representative of the programmable logic state (e.g., a charged capacitor may represent a first logic state, such as a logic 1; and an uncharged capacitor may represent a second logic state, such as a logic 0) of the memory cell 302. The transistor grants access to the capacitor upon application (e.g., by way of one of the word lines 306) of a minimum threshold voltage to a semiconductive channel thereof for operations (e.g., reading, writing, rewriting) on the capacitor. The transistor may be operably coupled to the capacitor by way of a conductive contact structure in electrical communication with and extending between the transistor and the capacitor.

The digit lines 304 are connected to the capacitors of the memory cells 302 by way of the transistors of the memory cells 302. The digit lines 304 may be separated (e.g., electrically isolated) from the conductive contact structures extending between the transistors and the capacitors of the memory cells 302. The word lines 306 extend perpendicular to the digit lines 304, and are connected to gates of the transistors of the memory cells 302. Operations may be performed on the memory cells 302 by activating appropriate digit lines 304 and word lines 306. Activating a digit line 304 or a word line 306 may include applying a voltage potential to the digit line 304 or the word line 306. Each column of memory cells 302 may individually be connected to one of the digit lines 304, and each row of the memory cells 302 may individually be connected to one of the word lines 306. Individual memory cells 302 may be addressed and accessed through the intersections (e.g., cross points) of the digit lines 304 and the word lines 306.

The memory controller 312 may control the operations of the memory cells 302 through various components, including the row decoder 308, the column decoder 310, and the sense device 314. The memory controller 312 may generate row address signals that are directed to the row decoder 308 to activate (e.g., apply a voltage potential to) predetermined word lines 306, and may generate column address signals that are directed to the column decoder 310 to activate (e.g., apply a voltage potential to) predetermined digit lines 304. The memory controller 312 may also generate and control various voltage potentials employed during the operation of the microelectronic device 300. In general, the amplitude, shape, and/or duration of an applied voltage may be adjusted (e.g., varied), and may be different for various operations of the microelectronic device 300.

During use and operation of the microelectronic device 300, after being accessed, a memory cell 302 may be read (e.g., sensed) by the sense device 314. The sense device 314 may compare a signal (e.g., a voltage) of an appropriate digit line 304 to a reference signal in order to determine the logic state of the memory cell 302. If, for example, the digit line 304 has a higher voltage than the reference voltage, the sense device 314 may determine that the stored logic state of the memory cell 302 is a logic 1, and vice versa. The sense device 314 may include transistors and amplifiers to detect and amplify a difference in the signals. The detected logic state of a memory cell 302 may be output through the column decoder 310 to the input/output device 316. In addition, a memory cell 302 may be set (e.g., written) by similarly activating an appropriate word line 306 and an appropriate digit line 304 of the microelectronic device 300. By controlling the digit line 304 while the word line 306 is activated, the memory cell 302 may be set (e.g., a logic value may be stored in the memory cell 302). The column decoder 310 may accept data from the input/output device 316 to be written to the memory cells 302. Furthermore, a memory cell 302 may also be refreshed (e.g., recharged) by reading the memory cell 302. The read operation will place the contents of the memory cell 302 on the appropriate digit line 304, which is then pulled up to full level (e.g., full charge or discharge) by the sense device 314. When the word line 306 connected to the memory cell 302 is deactivated, all of memory cells 302 in the row connected to the word line 306 are restored to full charge or discharge.

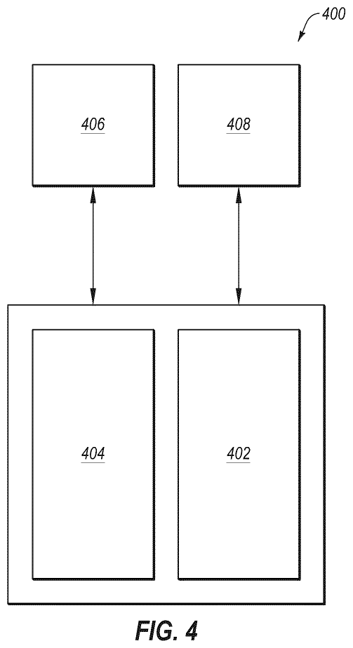

Microelectronic device structures (e.g., the microelectronic device structures 100, 200) and microelectronic devices (e.g., the microelectronic device 300 previously described with reference to FIG. 3) may be used in embodiments of electronic systems according to embodiments of the disclosure. Additional processing acts may be performed to form the electronic systems that contain one or more microelectronic device structures 100, 200 or one or more microelectronic devices 300. For example, FIG. 4 is a block diagram of an illustrative electronic system 400 according to embodiments of the disclosure. The electronic system 400 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 400 includes at least one memory device 402. The memory device 402 may comprise, for example, an embodiment of one or more of a microelectronic device structure (e.g., the microelectronic device structures 100, 200) and a microelectronic device (e.g., the microelectronic device 300). The electronic system 400 may further include at least one electronic signal processor device 404 (often referred to as a “microprocessor”). The electronic signal processor device 404 may, optionally, include an embodiment of the microelectronic device structures 100, 200 and/or the microelectronic device 300. The electronic system 400 may further include one or more input devices 406 for inputting information into the electronic system 400 by a user, such as, for example, a mouse or other pointing device, a keyboard, a touchpad, a button, or a control panel. The electronic system 400 may further include one or more output devices 408 for outputting information (e.g., visual or audio output) to a user such as, for example, a monitor, a display, a printer, an audio output jack, a speaker, etc. In some embodiments, the input device 406 and the output device 408 may comprise a single touchscreen device that can be used both to input information to the electronic system 400 and to output visual information to a user. The input device 406 and the output device 408 may communicate electrically with one or more of the memory device 402 and the electronic signal processor device 404.

The microelectronic device structures 100, 200, the microelectronic device 300, the electronic system 400, and methods of the disclosure may facilitate improved electrical performance, reduced costs (e.g., manufacturing costs, material costs), and increased miniaturization of components as compared to conventional structures, conventional apparatuses, conventional devices, conventional systems, and conventional methods. The structures, apparatuses, microelectronic devices, electronic systems, and methods of the disclosure may also improve scalability, efficiency, and simplicity as compared to conventional structures, conventional apparatuses, conventional devices, conventional systems, and conventional methods.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A microelectronic device comprising:
active areas, shallow trench isolation structures adjacent to the active areas, word lines adjacent to the shallow trench isolation structures, word line insulative structures adjacent to the word lines, and a dielectric stack over the active areas on a base material;
a first conductive material vertically adjacent to an active area of the active areas and between laterally adjacent word line insulative structures in a first horizontal direction;
a second conductive material vertically adjacent to the first conductive material, between the laterally adjacent word line insulative structures, and between laterally adjacent portions of the dielectric stack in the first horizontal direction;
a silicon carbon material on sidewalls of the dielectric stack; and
a digit line vertically adjacent to the second conductive material and to the dielectric stack, and between laterally adjacent digit line openings in a second horizontal direction substantially orthogonal to the first horizontal direction.

2. The microelectronic device of claim 1, wherein the silicon carbon material comprises silicon carbide or a doped silicon-containing material.

3. The microelectronic device of claim 1, wherein the sidewalls of the dielectric stack comprise sloped sidewalls.

4. The microelectronic device of claim 1, wherein sidewalls of the silicon carbon material contacting the second conductive material comprise substantially vertical sidewalls.

5. The microelectronic device of claim 1, wherein the silicon carbide material comprises a carbon content of from about 0.1 atomic percent to about 20 atomic percent.

6. The microelectronic device of claim 1, wherein the dielectric stack comprises a first dielectric material over the active areas and a second dielectric material over the first dielectric material.

7. The microelectronic device of claim 1, further comprising a nitride liner between the silicon carbon material and the dielectric stack.

8. The microelectronic device of claim 7, wherein sidewalls of the nitride liner contacting the second conductive material comprise substantially vertical sidewalls.

9. A method of forming a microelectronic device, comprising:
forming openings in a dielectric stack, the openings defined by sidewalls of the dielectric stack and upper surfaces of word line insulative structures and active areas;
forming a silicon carbon material on the sidewalls of the dielectric stack and on the word line insulative structures and the active areas;
exposing the silicon carbon material to a plasma, a horizontal portion of the silicon carbon material on the word line insulative structures and active areas exposed to a greater concentration of ions of the plasma than a portion of the silicon carbon material on the sidewalls of the dielectric stack;
removing the horizontal portion of the silicon carbon material on the word line insulative structures and active areas without substantially removing the portion of the silicon carbon material on the sidewalls of the dielectric stack;
removing a portion of the active area exposed between the portion of the silicon carbon material on the sidewalls of the dielectric stack; and
forming one or more conductive materials vertically adjacent to the active area.

10. The method of claim 9, wherein exposing the silicon carbon material to a plasma comprises reducing a carbon content of the horizontal portion of the silicon carbon material relative to the portion of the silicon carbon material on the sidewalls of the dielectric stack.

11. The method of claim 9, wherein removing the horizontal portion of the silicon carbon material on the word line insulative structures and active areas comprises removing the horizontal portion of the silicon carbon material using a wet etchant.

12. The method of claim 11, wherein removing the horizontal portion of the silicon carbon material using a wet etchant comprises forming substantially vertical sidewalls of the portion of the silicon carbon material on the sidewalls of the dielectric stack.

13. The method of claim 9, wherein forming a silicon carbon material on the sidewalls of the dielectric stack and on the word line insulative structures and the active areas comprises conformally forming the silicon carbon material.

14. The method of claim 9, wherein exposing the silicon carbon material to a plasma comprises exposing the silicon carbon material to an oxygen plasma, an oxygen/hydrogen gas/nitrogen gas plasma, a hydrogen gas/nitrogen gas plasma, or an oxygen/fluorocarbon plasma.

15. The method of claim 9, wherein removing a portion of the active area exposed between the portion of the silicon carbon material on the sidewalls of the dielectric stack comprises recessing an upper surface of the exposed active area.

16. The method of claim 15, wherein forming one or more conductive materials vertically adjacent to the active area comprises forming the one or more conductive materials vertically adjacent to the recessed active area.

17. A microelectronic device comprising:
active areas on a base material, shallow trench isolation structures adjacent to the active areas, word lines adjacent to the shallow trench isolation structures, word line insulative structures adjacent to the word lines, and a dielectric stack over the active areas;
a conductive material vertically adjacent to an active area of the active areas and between laterally adjacent word line insulative structures in a first horizontal direction;
a contact structure vertically adjacent to the conductive material and between laterally adjacent word line insulative structures in the first horizontal direction, an upper portion of the contact structure exhibiting a narrower width than a lower portion of the contact structure;
a silicon carbon material on sidewalls of the dielectric stack, an upper surface of the contact structure substantially coplanar with an upper surface of the silicon carbon material and an upper surface of the dielectric stack; and
a digit line vertically adjacent to the contact structure and to the dielectric stack in a second horizontal direction substantially orthogonal to the first horizontal direction, a width of the digit line substantially equal to the width of the upper portion of the contact structure.

18. The microelectronic device of claim 17, wherein the silicon carbon material comprises a carbon content of from about 0.1 atomic percent to about 20 atomic percent.

19. The microelectronic device of claim 17, wherein the silicon carbon material comprises a silicon carbon oxide material, a silicon carbon nitride material, a silicon carbon oxynitride material, a silicon carbon boride material, or a silicon carbon oxyboride carbide material.

20. The microelectronic device of claim 17, wherein the width of the upper portion of the contact structure material 128 is less than a width of the conductive material.
